(19) United States
(12) Patent Application Publication
(10) Pub. No.: US 2019/0264325 A1
(43) Pub. Date: Aug. 29, 2019

(54) ATOMIC LAYER DEPOSITION OF ELECTROCHEMICAL CATALYSTS

(71) Applicants: THE BOARD OF TRUSTEES OF THE LELAND STANFORD JUNIOR UNIVERSITY, Stanford, CA (US); VOLKSWAGEN AKTIENGESELLSCHAFT, Wolfsburg (DE)

(72) Inventors: Friedrich B. PRINZ, Stanford, CA (US); Thomas Francisco JARAMILLO, Stanford, CA (US); Tanja GRAF, Wolfsburg (DE); Thomas SCHLADT, Wolfsburg (DE); Gerold HUEBNER, Wolfsburg (DE); Shicheng XU, Stanford, CA (US); Yongmin KIM, Stanford, CA (US); Maha YUSUF, Stanford, CA (US); Drew Christopher HIGGINS, Stanford, CA (US)

(21) Appl. No.: 16/331,291

(22) PCT Filed: Sep. 7, 2017
(86) PCT No.: PCT/US2017/050540

§ 371 Date: Mar. 7, 2019

Related U.S. Application Data
(60) Provisional application No. 62/385,135, filed on Sep. 8, 2016.

(51) Int. Cl. C23C 16/455; H01M 4/92; H01M 8/10; H01M 4/88; C23C 16/02

(52) U.S. Cl. CPC C23C 16/45555; C23C 16/45527; H01M 4/926; H01M 2004/8689; H01M 4/8807; C23C 16/02; H01M 8/10

(57) ABSTRACT

A method includes (1) functionalizing a substrate to yield a functionalized substrate; and (2) depositing a catalyst on the functionalized substrate by atomic layer deposition to form a thin film of the catalyst covering the functionalized substrate.

### CROSS-REFERENCE TO RELATED APPLICATION

This application claims the benefit of U.S. Provisional Application No. 62/385,135, filed Sep. 8, 2016, the contents of which are incorporated herein by reference in their entirety.

### BACKGROUND

Polymer electrolyte membrane (PEM) fuel cells have a great potential as power sources for applications such as zero emission vehicles. However, state-of-the-art PEM fuel cells suffer from several drawbacks. One of the most challenging drawback is the amount of costly platinum group metals (PGMs) in form of nano-sized particles (or nanoparticles), which serve as electrochemical catalysts in a membrane electrode assembly (MEA) of a fuel cell. The amount of a PGM catalyst is typically determined by a power specification per unit cell in a fuel cell stack. However, a significant additional amount of a PGM catalyst is typically included to account for several degradation processes and to allow a reliable operation over a lifetime of a fuel cell. Typical degradation processes are associated with loss of a PGM material or loss of catalytically active surface area and include: PGM particle dissolution and corrosion, PGM particle growth through Ostwald ripening, PGM particle agglomeration, PGM particle detachment from a carbonaceous support, and corrosion of a carbonaceous support.

Small PGM nanoparticles are often unstable under fuel cell conditions and can have a tendency to dissolve due to their high surface-to-volume ratios. Therefore, small PGM nanoparticles (e.g., below about 2-3 nm) are often avoided. However, the utilization of larger particles leads to a higher amount of a PGM, which causes a rise in cost. Proposed solutions to reduce an amount of a PGM include alloying the PGM with a non-noble metal, core-shell structures of a non-noble core material covered by a PGM shell, or formation of a nanostructured thin film (NSTF). Although alloyed catalysts initially offer an enhanced catalytic activity, the alloyed catalysts can suffer from severe degradation due to dissolution of non-noble components. Furthermore, state-of-the-art synthesis techniques for PGM and PGM alloy catalysts typically rely on wet chemistry-type batch synthesis, which suffers from poor scalability, and which typically results in growth of nanoparticles with difficult shape and size control and with vulnerability towards corrosion, dissolution, and other degradation processes. Proposed core-shell structures suffer from a similar degradation process as for PGM alloy catalysts, since a non-noble core material can be prone to diffuse to a surface of a shell and dissolve under harsh PEM fuel cell conditions. While NSTFs can provide high activity and high stability at low PGM loading, formation of NSTFs involves specially structured supports. In the case of NSTFs, PGM is typically applied via physical vapor deposition (PVD), which is a non-conformal coating technique and therefore constrains a support structure to specific “zig-zag” architectures. Furthermore, NSTFs can suffer from severe water management problems owing to their whisker-like structure, which renders them impractical for low temperature PEM fuel cell operation.

It is against this background that a need arose to develop embodiments of this disclosure.

### SUMMARY

In some embodiments, a method includes: (1) functionalizing a substrate to yield a functionalized substrate; and (2) depositing a catalyst on the functionalized substrate by atomic layer deposition to form a thin film of the catalyst covering the functionalized substrate.

In some embodiments of the method, the substrate is a catalyst support.

In some embodiments of the method, the substrate is a porous, conductive material.

In some embodiments of the method, functionalizing the substrate includes applying a plasma treatment, an ozone treatment, an acid treatment, or a peroxide treatment to the substrate.

In some embodiments of the method, applying the plasma treatment includes applying a hydrogen plasma, an oxygen plasma, or a nitrogen plasma.

In some embodiments of the method, depositing the catalyst includes:

a) performing an atomic layer deposition cycle including
introducing precursors into a deposition chamber housing the functionalized substrate to deposit a material of the catalyst on the functionalized substrate; and
introducing a passivation gas into the deposition chamber to passivate a surface of the material; and

b) repeating a) a plurality of times to form the thin film of the catalyst.

In some embodiments of the method, depositing the catalyst includes:

a) performing an atomic layer deposition cycle including
introducing a first precursor into a deposition chamber housing the functionalized substrate such that the first precursor is adsorbed on the functionalized substrate; and
introducing a second passivation precursor into the deposition chamber to react with the first precursor adsorbed on the functionalized substrate to yield a material of the catalyst deposited on the functionalized substrate, and to passivate a surface of the material; and

b) repeating a) a plurality of times to form the thin film of the catalyst.

In additional embodiments, a method includes: (1) depositing a binding layer on a substrate to yield a binding layer-coated substrate; and (2) depositing a catalyst on the binding layer-coated substrate by atomic layer deposition to form a thin film of the catalyst covering the binding layer-coated substrate.

In some embodiments of the method, the substrate is a catalyst support.

In some embodiments of the method, the substrate is a porous, conductive material.

In some embodiments of the method, depositing the binding layer is performed by atomic layer deposition.

In some embodiments of the method, the binding layer includes at least one of a metal oxide, a metalloid oxide, a metal nitride, a metalloid nitride, a metal carbide, or a metalloid carbide.

In some embodiments of the method, depositing the catalyst includes:

a) performing an atomic layer deposition cycle including
introducing precursors into a deposition chamber housing the binding layer-coated substrate to deposit a material of the catalyst on the binding layer-coated substrate; and
introducing a passivation gas into the deposition chamber to passivate a surface of the material; and

b) repeating a) a plurality of times to form the thin film of the catalyst.

In some embodiments of the method, depositing the catalyst includes:

a) performing an atomic layer deposition cycle including
introducing a first precursor into a deposition chamber housing the binding layer-coated substrate such that the first precursor is adsorbed on the binding layer-coated substrate; and
introducing a second passivation precursor into the deposition chamber to react with the first precursor adsorbed on the binding layer-coated substrate to yield a material of the catalyst deposited on the binding layer-coated substrate, and to passivate a surface of the material; and

b) repeating a) a plurality of times to form the thin film of the catalyst.

Additional embodiments are directed to a structure obtained by the method of any of the foregoing embodiments.

In some embodiments, a supported catalyst includes: (1) a catalyst support; and (2) a thin film of a catalyst covering the catalyst support, wherein a surface coverage of the catalyst support by the thin film is at least 80%, and the thin film has an average thickness in a range from 1 atomic layer to 5 atomic layers.

In some embodiments of the supported catalyst, the average thickness of the thin film is in a range from 1 atomic layer to 3 atomic layers.

In some embodiments of the supported catalyst, the catalyst support is a carbonaceous support.

In some embodiments, the supported catalyst further includes a binding layer disposed between the thin film and the catalyst support.

In some embodiments of the supported catalyst, the binding layer includes at least one of a metal oxide, a metalloid oxide, a metal nitride, a metalloid nitride, a metal carbide, or a metalloid carbide.

In some embodiments of the supported catalyst, the catalyst includes a platinum group metal.

In additional embodiments, a fuel cell includes: (a) a cathode electrocatalyst layer; (b) an anode electrocatalyst layer; and (c) a polymeric ion-conductive membrane disposed between the cathode electrocatalyst layer and the anode electrocatalyst layer, wherein at least one of the cathode electrocatalyst layer or the anode electrocatalyst layer includes the supported catalyst of any of the foregoing embodiments.

In additional embodiments, a fuel cell includes: (a) a first gas diffusion layer; (b) a second gas diffusion layer; and (c) a polymeric ion-conductive membrane disposed between the first gas diffusion layer and the second gas diffusion layer, wherein at least one of the first gas diffusion layer or the second gas diffusion layer includes the supported catalyst of any of the foregoing embodiments.

In additional embodiments, a gas diffusion layer includes: (1) a porous, conductive material; and (2) a thin film of a catalyst covering the porous, conductive material.

In some embodiments of the gas diffusion layer, the porous, conductive material includes carbon cloth or carbon paper.

In some embodiments, the gas diffusion layer further includes a binding layer disposed between the thin film and the porous, conductive material.

In some embodiments of the gas diffusion layer, the binding layer includes at least one of a metal oxide, a metalloid oxide, a metal nitride, a metalloid nitride, a metal carbide, or a metalloid carbide.

In some embodiments of the gas diffusion layer, the catalyst includes a platinum group metal.

Further embodiments are directed to a fuel cell including the gas diffusion layer of any of the foregoing embodiments.

Other aspects and embodiments of this disclosure are also contemplated. The foregoing summary and the following detailed description are not meant to restrict this disclosure to any particular embodiment but are merely meant to describe some embodiments of this disclosure.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1. Schematic process flow of forming a thin film of a catalyst on a substrate, with functionalization of the substrate prior to deposition of the catalyst in a left panel, and with deposition of a binding layer on the substrate prior to deposition of the catalyst in a right panel.

FIG. 2. Schematic process flow of atomic layer deposition without passivation treatment in a left panel, atomic layer deposition incorporating the use of a passivation precursor in a middle panel, and atomic layer deposition incorporating the use of a passivation process gas in a right panel.

FIG. 3. Schematic process flow of atomic layer deposition without passivation treatment in a left panel, atomic layer deposition incorporating the use of a passivation precursor in a middle panel, and atomic layer deposition incorporating the use of a passivation process gas in a right panel.

FIG. 4. Schematic illustration of a structure of a supported catalyst, with a thin film of a catalyst covering a functionalized catalyst support in a left panel, and with a thin film of a catalyst covering a binding layer-coated catalyst support in a right panel.

FIG. 5. Schematic illustration of a structure of a thin film of a catalyst covering a porous, conductive material that can be used as a gas diffusion layer.

FIG. 6. Schematic illustration of a structure of a gas diffusion layer, which includes supported catalysts.

FIG. 7. Schematic illustration of a PEM fuel cell incorporating a supported catalyst disclosed herein.

FIG. 8. Schematic illustration of a PEM fuel cell incorporating a structure of a catalyst disclosed herein.

### DESCRIPTION

Embodiments of this disclosure are directed to an improved process of forming a substantially continuous thin film of a PGM (or an alloy or other multi-element material including the PGM) for highly stable and ultra-low loading catalysts for fuel cells, including PEM fuel cells, as well as a resulting structure of the thin film covering a substrate. The formation of a substantially continuous thin film of a catalyst provides higher stability compared to a nanoparticle form of the catalyst, as a result of the substantial absence of distinct surface defects, such as corners and edges, which are most prone to dissolution and corrosion, and the substantial immunity of the thin film to degradation processes impacting nanoparticles, such as Ostwald ripening and particle agglomeration. Through the use of atomic layer deposition, a thin film of a catalyst can be deposited with reduced thickness and high conformality. The reduced thickness of the thin film allows efficient use of the catalyst at low loading, and further translates into a higher mass activity with greater exposure of catalytic surface atoms in the thin film. Moreover, atomic layer deposition provides higher scalability compared to wet chemistry-type batch synthesis, and yields a conformal coating even for a high surface area or a high aspect ratio substrate. Furthermore, through either of, or both, functionalization of a substrate and deposition of a binding layer on the substrate prior to deposition of a catalyst, a thin film of the catalyst can be formed on a variety of substrates, without requiring a specially structured support. In some embodiments, a thin film of the catalyst can be formed on a carbonaceous support or other catalyst support, and, in other embodiments, a thin film of the catalyst can be directly formed on a gas diffusion layer without requiring an additional catalyst support.

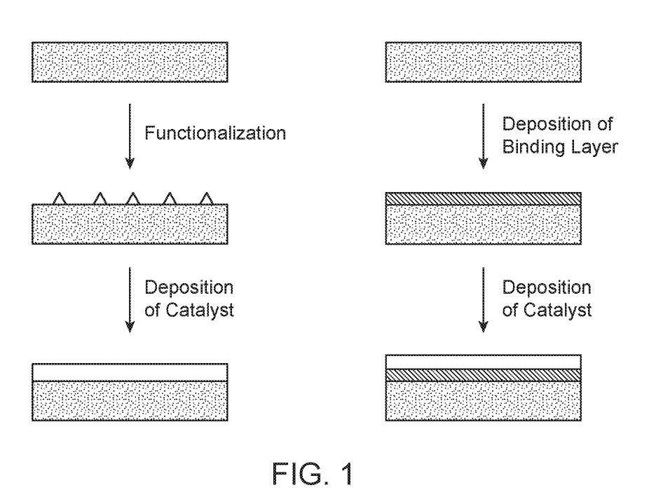

FIG. 1 is a schematic process flow of forming a thin film of a catalyst on a substrate, with functionalization of the substrate prior to deposition of the catalyst in a left panel, and with deposition of a binding layer on the substrate prior to deposition of the catalyst in a right panel. In some embodiments, the substrate is a catalyst support, such as a carbon-containing or carbonaceous support like carbon nanotubes, carbon nanohorns, carbon nanofibers, carbon nanoribbons, graphite, graphene sheets, carbon black, conductive carbon black, graphitized carbon, activated carbon, or other carbonaceous nanoparticles, or such as another non-carbon-based support, such as a metal oxide support, a metal nitride support, a metal carbide support, or other ceramic support. In other embodiments, the substrate is a porous, conductive material that can be used as a gas diffusion layer, such as carbon cloth, carbon paper, or other carbonaceous or non-carbon-based fibrous material. Other types of substrates can be used, through suitable functionalization or selection of a binding layer.

Referring to the left panel of FIG. 1, the process flow includes functionalizing the substrate to yield a functionalized substrate, followed by deposition of the catalyst on the functionalized substrate. Functionalizing the substrate is performed to introduce anchoring or functional groups to a surface of the substrate, to enhance or promote chemical bonding with precursors of the catalyst to be deposited on the substrate. In some embodiments, the substrate prior to functionalization is substantially devoid of anchoring groups and can be substantially inert towards deposition of the catalyst. For example, basal surfaces of pristine graphene sheets can be substantially inert toward atomic layer deposition of a PGM such as platinum (Pt), and performing atomic layer deposition of Pt on pristine graphene sheets can result in the formation of Pt nanoparticles on edges of the sheets. Functionalization of graphene sheets can involve the introduction of defect sites on basal surfaces, as manifested by, for example, the formation of sp³-hybridized carbon (instead of sp²-hybridized carbon in pristine graphene sheets), which promotes chemical bonding with precursors of the catalyst. In other embodiments, the substrate prior to functionalization includes some anchoring groups, and functionalization of the substrate introduces additional anchoring groups to yield a higher density and a higher uniformity of the anchoring groups across the surface of the substrate to promote subsequent formation of a substantially continuous thin film of the catalyst. Functionalizing the substrate can be performed by applying a plasma treatment, such as hydrogen plasma, oxygen plasma, or nitrogen plasma, and can result in the formation of, for example, hydrogen-containing anchoring groups (e.g., hydrogenation to introduce —C—H groups), oxygen-containing anchoring groups (e.g., groups containing a —C—O— moiety or a carbonyl moiety), nitrogen-containing anchoring groups, or a combination of such groups. In place of, or in combination with, a plasma treatment, functionalizing the substrate can be performed by ozone treatment, wet chemical treatment, such as using acids (e.g., oxidizing acid treatment using nitric acid boil), bases, peroxide treatment, or treatment with other reactive compounds, or by thermal treatment.

Still referring to the left panel of FIG. 1, deposition of the catalyst on the functionalized substrate is performed by chemical vapor deposition and, in particular, atomic layer deposition. Atomic layer deposition of the catalyst can be performed without passivation treatment in some embodiments and with passivation treatment in other embodiments.

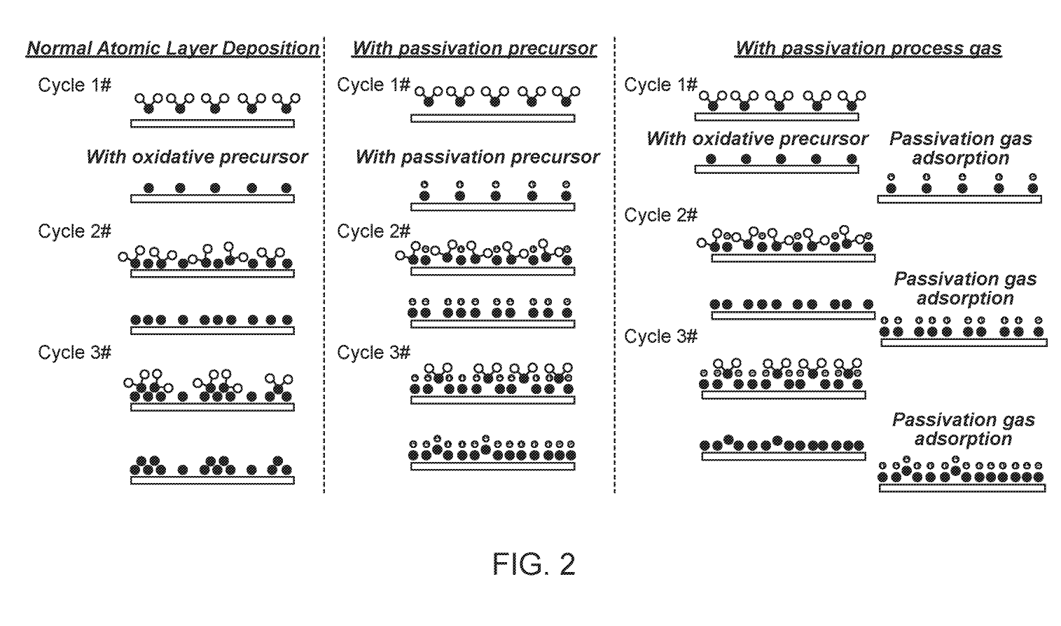

FIG. 2 is a schematic process flow of atomic layer deposition of the catalyst, with atomic layer deposition without passivation treatment in a left panel, with the use of a passivation precursor in a middle panel, and with the use of a passivation gas in a right panel. FIG. 2 illustrates deposition of the catalyst as a single element material, for example, a single PGM, although deposition of a binary element material, a ternary element material, or other multi-element material is also encompassed by this disclosure and is further explained below. The process flow of atomic layer deposition includes performing a first atomic layer deposition cycle to deposit the material on the substrate held within a deposition chamber, followed by performing a second atomic layer deposition cycle to deposit the material on the substrate, followed by performing a third atomic layer deposition cycle to deposit the material on the substrate, and so on until a requisite amount of the material is deposited.

Referring to the process flow in the left panel of FIG. 2, performing each atomic layer deposition cycle includes sequentially exposing the substrate, or a portion of the substrate, to deposition gases including a first precursor containing the material to be deposited, and a second oxidative precursor. In the case of a single element material, for example, the first precursor can be a PGM-containing precursor such as an organometallic compound with a PGM coordinated with organic ligands, and the second oxidative precursor can be oxygen, ozone, or oxygen plasma. For example, for the specific case of Pt, the first precursor can be (methyl cyclopentadienyl)trimethylplatinum or another Pt-containing organometallic compound. In addition to Pt, deposition can be performed for other PGMs, such as ruthenium (Ru), rhodium (Rh), palladium (Pd), osmium (Os), and iridium (Ir), as well as other noble metals, such as silver (Ag) and gold (Au). During the first atomic layer deposition cycle, the first precursor is introduced into the chamber to result in the first precursor being adsorbed to the substrate, in the form of molecules of the first precursor, residues of the molecules of the first precursor, or a combination of both, and the second oxidative precursor is introduced into the chamber to result in a reaction between the adsorbed first precursor and the second oxidative precursor to liberate ligands included in the adsorbed first precursor, thereby leaving the material deposited on the substrate. Anchoring groups on the substrate (introduced through functionalization) promotes adsorption of the first precursor to the substrate at a higher density and in a more uniform manner. In some embodiments, anchoring groups on the substrate can undergo a reaction with the adsorbed first precursor to result in the formation of bonds or linkages between carbon atoms of the substrate and metal atoms included in the adsorbed first precursor, either directly or indirectly through one or more intervening atoms, such as oxygen or nitrogen atoms. A second reductive precursor, such as hydrogen or hydrogen plasma, can be used in place of, or in combination with, the second oxidative precursor. A removal operation can be performed subsequent to introducing each precursor to remove reaction products and any unreacted precursor, such as by evacuation or purging with an inert carrier gas.

Referring to the process flow in the right panel of FIG. 2, a passivation gas is introduced into the chamber subsequent to introducing precursors in each atomic layer deposition cycle, including the first atomic layer deposition cycle, and prior to introducing precursors in a subsequent atomic layer deposition cycle. The passivation gas serves to tune or change an adsorption energy between the first precursor and the already-deposited material to render that adsorption energy less favorable such that subsequent adsorption of the first precursor will be preferential or promoted towards covering vacant areas of the substrate instead of the already-deposited material. In such manner, the use of the passivation gas enhances dispersion of the first precursor along the substrate and leads to enhanced and more uniform coverage of deposited material along the substrate, as well as allowing control over that coverage. In some embodiments, criteria for the passivation gas include one or more of the following: 1) ability to adsorb onto the deposited material; 2) exhibits greater tendency towards or has a stronger adsorption onto the deposited material compared to the substrate; 3) after adsorption onto the deposited material, the passivation gas forms an intermediate chemical species; and 4) an adsorption energy of the first precursor to the intermediate species is greater than (e.g., less negative or more positive than) about −10 kJ/mol (or greater than about −0.104 eV), such as about −5 kJ/mol or greater (or about −0.052 eV or greater), about 0 kJ/mol or greater (or about 0 eV or greater), or about 10 kJ/mol or greater (or about 0.104 eV or greater), or the adsorption energy of the first precursor to the intermediate species is greater than an adsorption energy of the first precursor to the substrate. For example, for the case of Pt or another single element material, the passivation gas can be carbon monoxide (CO). In addition to CO, other passivation gases satisfying the above-noted criteria can be used, such as ammonia (NH₃), nitric oxide (NO), and methane (CH₄). A process temperature can be controlled to mitigate against desorption of the passivation gas. For example, for the case of CO or another passivation gas, a temperature of the substrate can be controlled to be in a range from about 50° C. to about 250° C., from about 80° C. to about 200° C., or from about 100° C. to about 150° C.

Referring next to the process flow in the middle panel of FIG. 2, performing each atomic layer deposition cycle includes sequentially exposing the substrate, or a portion of the substrate, to deposition gases including a first precursor containing the material to be deposited, and a second passivation precursor. Certain aspects of the process flow in the middle panel can be similarly performed as explained above for the right panel, and those aspects are not repeated. Here, the passivation precursor serves dual functions of reacting with the first precursor adsorbed to the substrate to liberate ligands included in the adsorbed first precursor, and tuning or changing an adsorption energy between the first precursor and the already-deposited material to render that adsorption energy less favorable such that subsequent adsorption of the first precursor will be preferential or promoted towards covering vacant areas of the substrate instead of the already-deposited material. In such manner, the use of the passivation precursor enhances dispersion of the first precursor along the substrate and leads to enhanced and more uniform coverage of deposited material along the substrate, as well as allowing control over that coverage. In some embodiments, criteria for the passivation precursor include one or more of the following: 1) ability to react with the first precursor to form an intermediate chemical species; and 2) an adsorption energy of the first precursor to the intermediate species is greater than (e.g., less negative or more positive than) about −10 kJ/mol (or greater than about −0.104 eV), such as about −5 kJ/mol or greater (or about −0.052 eV or greater), about 0 kJ/mol or greater (or about 0 eV or greater), or about 10 kJ/mol or greater (or about 0.104 eV or greater), or the adsorption energy of the first precursor to the intermediate species is greater than an adsorption energy of the first precursor to the substrate. In some embodiments, the passivation precursor includes a passivation ligand or another passivation chemical moiety that remains adsorbed on the first precursor, subsequent to reaction of the passivation precursor with the first precursor. For example, the passivation moiety can have a chemical structure corresponding to, or similar to, that of a passivation gas explained above.

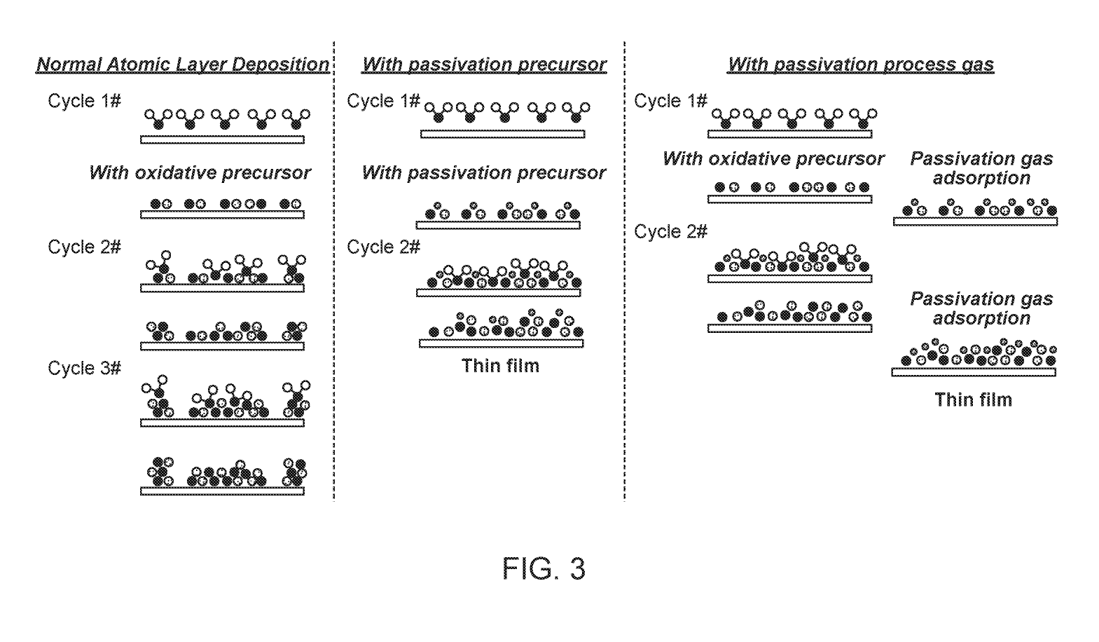

In addition to deposition of a single element material explained above, atomic layer deposition also can be applied for deposition of multi-element materials. FIG. 3 is a schematic process flow of atomic layer deposition of the catalyst, with atomic layer deposition without passivation treatment in a left panel, with the use of a passivation precursor in a middle panel, and with the use of a passivation gas in a right panel. FIG. 3 illustrates deposition of the catalyst as a binary element material by way of example, although deposition of a ternary element material or other multi-element material is also encompassed by this disclosure. The process flow of atomic layer deposition includes performing a first atomic layer deposition cycle to deposit the material on the substrate held within the deposition chamber, followed by performing a second atomic layer deposition cycle to deposit the material on the substrate, followed by performing a third atomic layer deposition cycle to deposit the material on the substrate, and so on until a requisite amount of the material is deposited. Certain aspects of the process flow in FIG. 3 can be similarly performed as explained above for FIG. 2, and those aspects are not repeated.

Referring to the process flow in the left panel of FIG. 3, performing each atomic layer deposition cycle includes sequentially exposing the substrate, or a portion of the substrate, to deposition gases including a first precursor containing a first element of the material to be deposited, a second precursor containing a second element of the material to be deposited, and a third oxidative precursor. In the case of a binary element material, for example, the first precursor and the second precursor can be different metal-containing precursors, such as different organometallic compounds with respective metals coordinated with organic ligands. The first element can be a PGM, and the second element can be a different PGM, or other noble metal, or other transition metal, such as scandium (Sc), titanium (Ti), vanadium (V), chromium (Cr), manganese (Mn), iron (Fe), cobalt (Co), nickel (Ni), copper (Cu), or zinc (Zn). During the first atomic layer deposition cycle, the first precursor is introduced into the chamber to result in the first precursor being adsorbed to the substrate, the second precursor is introduced into the chamber to result in the second precursor being adsorbed to the substrate, and the third oxidative precursor is introduced into the chamber to result in a reaction between the adsorbed first precursor, the adsorbed second precursor, and the third oxidative precursor to liberate ligands included in the adsorbed first precursor and the adsorbed second precursor, thereby leaving the material deposited on the substrate. A third reductive precursor, such as hydrogen or hydrogen plasma, can be used in place of, or in combination with, the third oxidative precursor. Also, the second precursor can perform an oxidative or a reductive function with respect to the first precursor, such that a separate oxidative or reductive precursor can be omitted. A removal operation can be performed subsequent to introducing each precursor to remove reaction products and any unreacted precursor, such as by evacuation or purging with an inert carrier gas.

Referring to the process flow in the right panel of FIG. 3, a passivation gas is introduced into the chamber subsequent to introducing precursors in each atomic layer deposition cycle, and prior to introducing precursors in a subsequent atomic layer deposition cycle. The passivation gas serves to tune or change adsorption energies between the first precursor and the already-deposited material and between the second precursor and the already-deposited material to render those adsorption energies less favorable such that subsequent adsorption of the first precursor and the second precursor will be preferential or promoted towards covering vacant areas of the substrate instead of the already-deposited material. In such manner, the use of the passivation gas enhances dispersion of the first precursor and the second precursor along the substrate and leads to enhanced and more uniform coverage of deposited material along the substrate, as well as allowing control over that coverage. It is also contemplated that two or more different passivation gases can be used, such as a first passivation gas that preferentially absorbs onto the first element of the deposited material to tune or change an adsorption energy with respect to the first element, and a second passivation gas that preferentially absorbs onto the second element of the deposited material to tune or change an adsorption energy with respect to the second element.

Referring next to the process flow in the middle panel of FIG. 3, performing each atomic layer deposition cycle includes sequentially exposing the substrate, or a portion of the substrate, to deposition gases including a first precursor containing a first element of the material to be deposited, a second precursor containing a second element of the material to be deposited, and a third passivation precursor. Here, the passivation precursor serves dual functions of reacting with the first precursor and the second precursor adsorbed to the substrate to liberate ligands included in the adsorbed first precursor and the adsorbed second precursor, and tuning or changing adsorption energies between the first precursor and the already-deposited material and between the second precursor and the already-deposited material to render those adsorption energies less favorable such that subsequent adsorption of the first precursor and the second precursor will be preferential or promoted towards covering vacant areas of the substrate instead of the already-deposited material. In such manner, the use of the passivation precursor enhances dispersion of the first precursor and the second precursor along the substrate and leads to enhanced and more uniform coverage of deposited material along the substrate, as well as allowing control over that coverage. It is also contemplated that two or more different passivation precursors can be used, such as a first passivation precursor that preferentially reacts with the first precursor adsorbed to the substrate to tune or change an adsorption energy with respect to the first element, and a second passivation precursor that preferentially reacts with the second precursor adsorbed to the substrate to tune or change an adsorption energy with respect to the second element.

Referring to back to FIG. 1 and, in particular, the right panel of FIG. 1, the process flow includes depositing the binding layer on the substrate to yield a binding layer-coated substrate, followed by deposition of the catalyst on the binding layer-coated substrate. The binding layer includes a material that bonds strongly to both the substrate and the catalyst for improved stability. In some embodiments, the binding layer includes anchoring or functional groups on a surface of the binding layer, to enhance or promote chemical bonding with precursors of the catalyst to be deposited on the substrate. The binding layer may provide additional benefits, such as an increase in catalytic activity due to structural (e.g., lattice strain) and electronic (e.g., d-band center shift) effects. Examples of the material of the binding layer include metal oxides, metalloid oxides, metal nitrides, metalloid nitrides, metal carbides, metalloid carbides, and other ceramics. Depositing the binding layer is performed by chemical vapor deposition and, in particular, atomic layer deposition. In the case of a binary element material, for example, performing each atomic layer deposition cycle includes sequentially exposing the substrate, or a portion of the substrate, to deposition gases including a first precursor containing a first element of the material to be deposited, a second precursor containing a second element of the material to be deposited, and a third oxidative precursor. For example, the first element can be a metal or a metalloid, and the second element can be oxygen, nitrogen, or carbon. A third reductive precursor can be used in place of, or in combination with, the third oxidative precursor. Also, the second precursor can perform an oxidative or a reductive function with respect to the first precursor, such that a separate oxidative or reductive precursor can be omitted. Certain aspects of atomic layer deposition of the binding layer can be similarly performed as explained above for FIG. 3, and those aspects are not repeated. An average thickness of the binding layer can be in a range of about 1 nm to about 100 nm or more, such as from about 1 nm to about 50 nm, from about 1 nm to about 40 nm, from about 1 nm to about 30 nm, from about 1 nm to about 20 nm, or from about 1 nm to about 10 nm.

Subsequent to deposition of the binding layer, deposition of the catalyst on the binding layer-coated substrate is performed by chemical vapor deposition and, in particular, atomic layer deposition. Atomic layer deposition of the catalyst can be performed without passivation treatment in some embodiments and with passivation treatment in other embodiments. Certain aspects of atomic layer deposition of the catalyst can be similarly performed as explained above for FIGS. 2 and 3, and those aspects are not repeated. Although FIG. 1 illustrates functionalization of the substrate and deposition of the binding layer as alternatives, both treatments can be performed in other embodiments. For example, the substrate can be functionalized to yield a functionalized substrate, followed by deposition of the binding layer on the functionalized substrate, and followed by deposition of the catalyst.

Referring to both left and right panels of FIG. 1, deposition of the catalyst by atomic layer deposition results in the formation of a substantially continuous thin film of the catalyst that is highly stable and with ultra-low loading of the catalyst. Compared to atomic layer deposition without passivation treatment, passivation-incorporated atomic layer deposition allows greater control over deposition to attain enhanced coverage of the deposited catalyst with a reduced thickness down to a single atomic layer or a few atomic layers. By incorporating a passivation treatment, the process flow provides self-limiting atomic monolayer (or near atomic monolayer) deposition of the catalyst, and overcomes nucleation tendencies that may otherwise restrict a minimum thickness (typically several atomic layers) for requisite coverage of the substrate. Further, the passivation-incorporated process flow still retains the benefits of atomic layer deposition, including a self-saturation nature for greater thickness control and an ability to conformally deposit a material on high surface area or high aspect ratio surfaces.

In some embodiments, the resulting thin film of the catalyst provides a surface coverage of the substrate of at least about 30%, such as at least about 40%, at least about 50%, at least about 60%, at least about 70%, at least about 80%, at least about 90%, at least about 95%, at least about 98%, at least about 98.5%, or at least about 99%, and up to about 100%, with an average thickness in a range from about 1 atomic layer to about 5 atomic layers, from about 1 atomic layer to about 4 atomic layers, from about 1 atomic layer to about 3 atomic layers, from about 1 atomic layer to about 2 atomic layers, or from about 1 atomic layer to about 1.5 atomic layers, and with a surface roughness (root mean square) of no greater than about 80% of the average thickness, such as no greater than about 70%, no greater than about 60%, no greater than about 50%, no greater than about 40%, no greater than about 30%, no greater than about 20%, no greater than about 15%, or no greater than about 10%. Surface coverage of the thin film can be assessed using imaging techniques, such as using transmission electron microscopy (TEM) or scanning electron microscopy (TEM) images, backscattering spectroscopy, X-ray photoelectron spectroscopy (XPS), or inductively coupled plasma mass spectrometry (ICP-MS). In the case of a single element material, 1 atomic layer can correspond to a thickness of a single layer of atoms of the element. In the case of a binary element material having a molar composition of a % of a first element and b % of a second element, 1 atomic layer can correspond to a thickness of a single layer of atoms having an effective size given by (a/100)×(size of an atom of the first element)+(b/100)×(size of an atom of the second element). A similar weighted average according to a molar composition can be used to specify a thickness of 1 atomic layer for a ternary element material or other multi-element material.

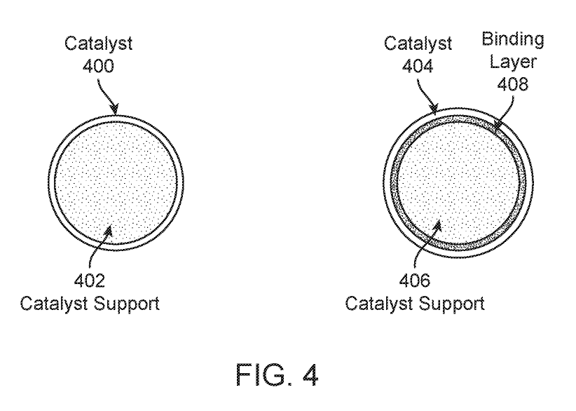

FIG. 4 is a schematic illustration of a structure of a supported catalyst, with a thin film of a catalyst 400 covering a functionalized catalyst support 402 in a left panel, and with a thin film of a catalyst 404 covering a catalyst support 406 coated with a binding layer 408 in a right panel. Here, the catalyst support 402 or 406 is in the form of a nanoparticle, such as a carbonaceous nanoparticle having a size in a range of about 5 nm to about 500 nm or more, such as from about 10 nm to about 400 nm, from about 10 nm to about 300 nm, from about 10 nm to about 200 nm, from about 10 nm to about 150 nm, or from about 10 nm to about 100 nm, and having an aspect ratio of about 3 or less, or about 2 or less. Other types of catalyst supports can be used, such as carbon nanohorns, carbon nanofibers, carbon nanoribbons, graphite, and graphene sheets, as well as non-carbon-based supports. Referring to the left panel of FIG. 4, the catalyst support 402 is functionalized to promote bonding with the catalyst 400 that is deposited on the functionalized catalyst support 402. Referring to the right panel of FIG. 4, the binding layer 408 covers the catalyst support 406 and is disposed between the thin film of the catalyst 404 and the catalyst support 406.

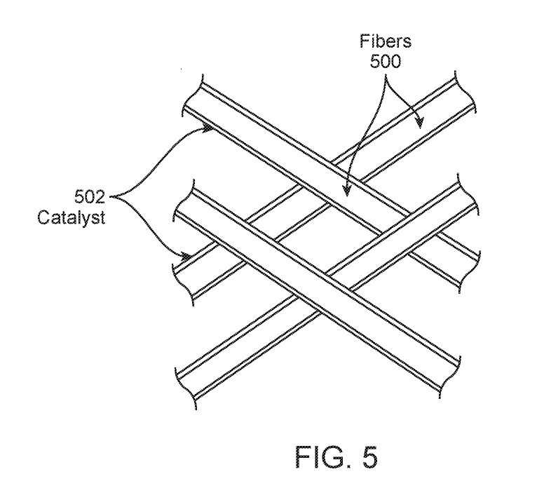

FIG. 5 is a schematic illustration of a structure of a thin film of a catalyst covering a porous, conductive material that can be used as a gas diffusion layer. Here, the porous, conductive material is in the form of a carbonaceous fibrous material, such as carbon cloth or carbon paper, although other carbonaceous or non-carbon-based fibrous materials can be used. Referring to FIG. 5, individual fibers 500 of the carbonaceous fibrous material are conformally covered by the thin film of the catalyst 502, and, in some embodiments, the fibers 500 can be functionalized to promote bonding with the catalyst 502, and, in other embodiments, a binding layer can be deposited to conformally cover the fibers 500 and can be disposed between the thin film of the catalyst 502 and the fibers 500.

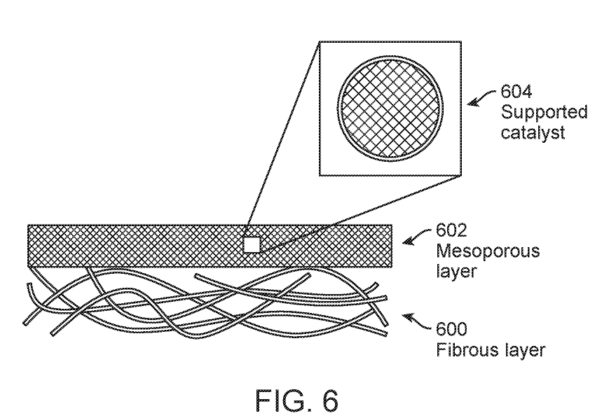

FIG. 6 is a schematic illustration of a structure of a gas diffusion layer, which includes a carbonaceous fibrous layer 600, such as carbon cloth or carbon paper, although other carbonaceous or non-carbon-based fibrous materials can be used. The gas diffusion layer also includes a mesoporous layer 602. The carbonaceous fibrous layer 600 is covered by the mesoporous layer 602. The mesoporous layer 602 includes supported catalysts 604, along with a polymeric binder and a fluorinated polymer to control water transport. The supported catalysts 604 can be implemented as explained in connection with FIG. 4.

Various applications of fuel cells can benefit from the structure of a catalyst disclosed herein. Examples include:

1) Fuel cell powered vehicles, such as cars, buses, trucks, and motorcycles;

2) Stationary fuel cell applications; and

3) Fuel cells in consumer electronic products.

Various types of fuel cells can benefit from the structure of a catalyst disclosed herein. Examples include H₂—PEM fuel cells, methanol fuels, and ethanol fuel cells, amongst others.

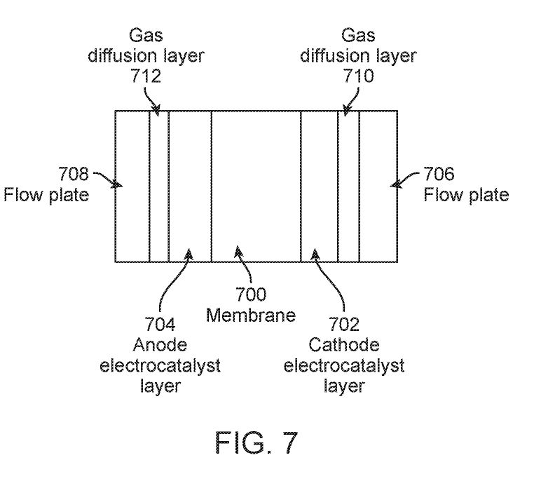

FIG. 7 is a schematic illustration of a PEM fuel cell incorporating a supported catalyst disclosed herein. The fuel cell includes a polymeric ion-conductive membrane 700 disposed between a cathode electrocatalyst layer 702 and an anode electrocatalyst layer 704, which together constitute a membrane electrode assembly of the fuel cell. The fuel cell also includes electrically conductive flow field plates 706 and 708, which can be bipolar plates or unipolar plates. Gas diffusion layers 710 and 712 are also interposed between the flow field plates 706 and 708 and the electrocatalyst layers 702 and 704. Either of, or both, the cathode electrocatalyst layer 702 and anode electrocatalyst layer 704 can include a supported catalyst disclosed herein. For example, the supported catalyst can promote oxygen reduction reaction at the cathode side when incorporated into the cathode electrocatalyst layer 702, and also can promote hydrogen oxidation reaction at the anode side when incorporated into the anode electrocatalyst layer 704.

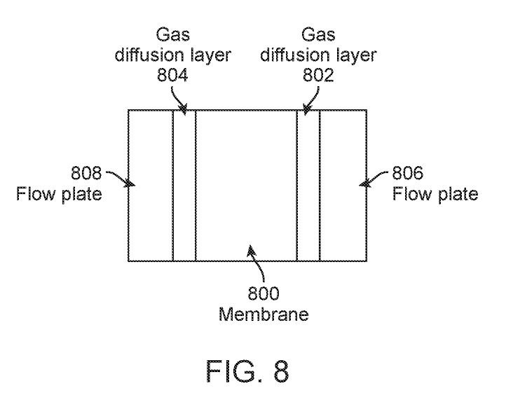

FIG. 8 is a schematic illustration of another PEM fuel cell incorporating the structure of a catalyst disclosed herein. The fuel cell includes a polymeric ion-conductive membrane 800 disposed between gas diffusion layers 802 and 804, which are, in turn, disposed between electrically conductive flow field plates 806 and 808, which can be bipolar plates or unipolar plates. Either of, or both, the gas diffusion layer 802 at the cathode side and the gas diffusion layer 804 at the anode side can include a thin film of a catalyst covering a porous, conductive material, or a supported catalyst. For example, the catalyst can promote oxygen reduction reaction when incorporated into the gas diffusion layer 802 at the cathode side, and also can promote hydrogen oxidation reaction when incorporated into the gas diffusion layer 804 at the anode side. By directly forming or incorporating the catalyst in the gas diffusion layer 802 or 804, an additional layer including a catalyst support can be omitted.

As used herein, the singular terms “a,” “an,” and “the” may include plural referents unless the context clearly dictates otherwise. Thus, for example, reference to an object may include multiple objects unless the context clearly dictates otherwise.

As used herein, the terms “substantially,” “substantial,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the term “size” refers to a characteristic dimension of an object. Thus, for example, a size of an object that is spherical can refer to a diameter of the object. In the case of an object that is non-spherical, a size of the object can refer to a diameter of a corresponding spherical object, where the corresponding spherical object exhibits or has a particular set of derivable or measurable characteristics that are substantially the same as those of the non-spherical object. When referring to a set of objects as having a particular size, it is contemplated that the objects can have a distribution of sizes around the particular size. Thus, as used herein, a size of a set of objects can refer to a typical size of a distribution of sizes, such as an average size, a median size, or a peak size.

In the description of some embodiments, an object “on” another object can encompass cases where the former object is directly on (e.g., in physical contact with) the latter object, as well as cases where one or more intervening objects are located between the former object and the latter object.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a range of about 1 to about 200 should be understood to include the explicitly recited limits of about 1 and about 200, but also to include individual values such as about 2, about 3, and about 4, and sub-ranges such as about 10 to about 50, about 20 to about 100, and so forth.

While this disclosure has been described with reference to the specific embodiments thereof, it should be understood by those skilled in the art that various changes may be made and equivalents may be substituted without departing from the true spirit and scope of this disclosure as defined by the appended claims. In addition, many modifications may be made to adapt a particular situation, material, composition of matter, method, operation or operations, to the objective, spirit and scope of this disclosure. All such modifications are intended to be within the scope of the claims appended hereto. In particular, while certain methods may have been described with reference to particular operations performed in a particular order, it will be understood that these operations may be combined, sub-divided, or re-ordered to form an equivalent method without departing from the teachings of this disclosure. Accordingly, unless specifically indicated herein, the order and grouping of the operations are not a limitation of this disclosure.

1. A method comprising:
functionalizing a substrate to yield a functionalized substrate; and
depositing a catalyst on the functionalized substrate by atomic layer deposition to form a thin film of the catalyst covering the functionalized substrate.

2. The method of claim 1, wherein the substrate is a catalyst support.

3. The method of claim 1, wherein the substrate is a porous, conductive material.

4. The method of claim 1, wherein functionalizing the substrate includes applying a plasma treatment, an ozone treatment, an acid treatment, or a peroxide treatment to the substrate.

5. The method of claim 4, wherein applying the plasma treatment includes applying a hydrogen plasma, an oxygen plasma, or a nitrogen plasma.

6. The method of claim 1, wherein depositing the catalyst includes:
1) performing an atomic layer deposition cycle including
introducing precursors into a deposition chamber housing the functionalized substrate to deposit a material of the catalyst on the functionalized substrate; and
introducing a passivation gas into the deposition chamber to passivate a surface of the material; and
2) repeating 1) a plurality of times to form the thin film of the catalyst.

7. The method of claim 1, wherein depositing the catalyst includes:
1) performing an atomic layer deposition cycle including
introducing a first precursor into a deposition chamber housing the functionalized substrate such that the first precursor is adsorbed on the functionalized substrate; and
introducing a second passivation precursor into the deposition chamber to react with the first precursor adsorbed on the functionalized substrate to yield a material of the catalyst deposited on the functionalized substrate, and to passivate a surface of the material; and
2) repeating 1) a plurality of times to form the thin film of the catalyst.

8. A method comprising:
depositing a binding layer on a substrate to yield a binding layer-coated substrate; and
depositing a catalyst on the binding layer-coated substrate by atomic layer deposition to form a thin film of the catalyst covering the binding layer-coated substrate.

9. The method of claim 8, wherein the substrate is a catalyst support.

10. The method of claim 8, wherein the substrate is a porous, conductive material.

11. The method of claim 8, wherein depositing the binding layer is performed by atomic layer deposition.

12. The method of claim 8, wherein the binding layer includes at least one of a metal oxide, a metalloid oxide, a metal nitride, a metalloid nitride, a metal carbide, or a metalloid carbide.

13. The method of claim 8, wherein depositing the catalyst includes:
1) performing an atomic layer deposition cycle including
introducing precursors into a deposition chamber housing the binding layer-coated substrate to deposit a material of the catalyst on the binding layer-coated substrate; and
introducing a passivation gas into the deposition chamber to passivate a surface of the material; and
2) repeating 1) a plurality of times to form the thin film of the catalyst.

14. The method of claim 8, wherein depositing the catalyst includes:
1) performing an atomic layer deposition cycle including
introducing a first precursor into a deposition chamber housing the binding layer-coated substrate such that the first precursor is adsorbed on the binding layer-coated substrate; and
introducing a second passivation precursor into the deposition chamber to react with the first precursor adsorbed on the binding layer-coated substrate to yield a material of the catalyst deposited on the binding layer-coated substrate, and to passivate a surface of the material; and
2) repeating 1) a plurality of times to form the thin film of the catalyst.

15. A structure obtained by the method of any one of claim 1 or 8.

16. A supported catalyst comprising:
a catalyst support; and
a thin film of a catalyst covering the catalyst support,
wherein a surface coverage of the catalyst support by the thin film is at least 80%, and the thin film has an average thickness in a range from 1 atomic layer to 5 atomic layers.

17. The supported catalyst of claim 16, wherein the average thickness of the thin film is in a range from 1 atomic layer to 3 atomic layers.

18. The supported catalyst of claim 16, wherein the catalyst support is a carbonaceous support.

19. The supported catalyst of claim 16, further comprising a binding layer disposed between the thin film and the catalyst support.

20. The supported catalyst of claim 19, wherein the binding layer includes at least one of a metal oxide, a metalloid oxide, a metal nitride, a metalloid nitride, a metal carbide, or a metalloid carbide.

21. The supported catalyst of claim 16, wherein the catalyst includes a platinum group metal.

22. A fuel cell comprising:
a cathode electrocatalyst layer;
an anode electrocatalyst layer; and
a polymeric ion-conductive membrane disposed between the cathode electrocatalyst layer and the anode electrocatalyst layer,
wherein at least one of the cathode electrocatalyst layer or the anode electrocatalyst layer includes the supported catalyst of claim 16.

23. A fuel cell comprising:
a first gas diffusion layer;
a second gas diffusion layer; and
a polymeric ion-conductive membrane disposed between the first gas diffusion layer and the second gas diffusion layer,
wherein at least one of the first gas diffusion layer or the second gas diffusion layer includes the supported catalyst of claim 16.

24. A gas diffusion layer comprising:
a porous, conductive material; and
a thin film of a catalyst covering the porous, conductive material.

25. The gas diffusion layer of claim 24, wherein the porous, conductive material includes carbon cloth or carbon paper.

26. The gas diffusion layer of claim 24, further comprising a binding layer disposed between the thin film and the porous, conductive material.

27. The gas diffusion layer of claim 26, wherein the binding layer includes at least one of a metal oxide, a metalloid oxide, a metal nitride, a metalloid nitride, a metal carbide, or a metalloid carbide.

28. The gas diffusion layer of claim 24, wherein the catalyst includes a platinum group metal.

29. A fuel cell comprising the gas diffusion layer of claim 24.
